(19) United States
(12) Patent Application Publication
(10) Pub. No.: US 2005/0208779 A1
(43) Pub. Date: Sep. 22, 2005

(54) Imprint lithography process

(76) Inventors: Hagen Klauk, Erlangen (DE); Gunter Schmid, Hemhofen (DE); Marcus Halik, Erlangen (DE); Ute Zschieschang, Erlangen (DE)

Correspondence Address: SLATER & MATSIL LLP, 17950 PRESTON ROAD, SUITE 1000, DALLAS, TX, 75252, US

(21) Appl. No.: 11/046,662

(22) Filed: Jan. 28, 2005

(30) Foreign Application Priority Data
Jan. 28, 2004 (DE) 10 2004 005 247.6

(51) Int. Cl. H01L 21/4763; H01L 21/324

(52) U.S. Cl. 438/795; 438/622

(57) ABSTRACT

An imprint lithography process is used for the production of a semiconductor component. A polymeric gate dielectric layer (12) is structured in the absence of a resist solely by at least one imprint die (20). Before and/or after the structuring by means of the imprint die (20), the polymer layer is cured and/or crosslinked. The curing and/or crosslinking is induced thermally and/or by light.

This application claims priority to German Patent Application 10 2004 005 247.6-51, which was filed Jan. 28, 2004, and is incorporated herein by reference.

### TECHNICAL FIELD

The invention relates to an imprint lithography process for the production of a semiconductor component.

### BACKGROUND

The mode of operation of field effect transistors is based on the modulation of the concentration of freely mobile charge carriers in a semiconductor layer by application of a controllable electrical voltage to a gate electrode.

In MISFETs (“metal-insulator-semiconductor field effect transistors”), a thin layer of an insulating material, which is referred to as the gate dielectric, is used for the electrical insulation of the gate electrode from the semiconductor layer. In conventional field effect transistors, these are, as a rule, inorganic dielectrics, such as, for example, silicon dioxide (transistors having oxide dielectrics are also referred to as MOSFETs, “metal-oxide-semiconductor field effect transistors”).

Particularly for field effect transistors based on organic semiconductors, however, gate dielectrics based on organic polymers are of interest since the processing of thin polymer layers is, as a rule, more economical and can be effected at lower temperatures compared with the processing of inorganic dielectrics.

Organic field effect transistors are of interest, inter alia, for realizing simple integrated circuits. The production of integrated circuits based on field effect transistors requires, inter alia, targeted structuring of the gate dielectric layer, since targeted access to the electrodes or contacts in the metallization plane or the metallization planes below the insulating layer can be established only by the opening of plated-through holes (contact holes, “vias”) in the insulating layer. Access to the metallization planes present below the insulating layer is necessary particularly if the input of a transistor is to be connected to the output of another transistor, as is often essential in every integrated circuit.

It is known that contact holes can be opened, for example, by means of photolithography and etching. A photoresist is applied to the dielectric, exposed to light through a photomask and then developed. The photoresist structured in this manner subsequently serves as a mask in a dry or wet chemical etching step for opening the contact hole; finally, the photoresist is removed again.

Particularly for economical applications of organic integrated circuits, process methods which manage without relatively expensive apparatuses and procedures necessary for photolithography are of interest.

One example is imprint lithography (e.g. WO 00/54107 A1), which was developed as an alternative to photolithography in the production of integrated silicon circuits. In imprint lithography, the desired structures are transferred from a relief die to a thin polymer layer applied beforehand to the silicon wafer. As a result of the mechanical pressure of the elevated areas of the die, there is a targeted molding of the polymer in these regions. Before removal of the die, the molded polymer layer is cured or crosslinked either thermally or by exposure to ultraviolet light so that the structures imparted by means of the die are retained in the polymer. The structures are then transferred to the substrate underneath by plasma etching; the polymer layer serves as a resist. Finally, the polymer layer is removed again.

Thus, imprint lithography, also, requires an etching step, which increases the effort in the production of the semiconductor circuits.

### SUMMARY OF THE INVENTION

In one aspect, the present invention provides a process by means of which semiconductor circuits can be produced in a particularly simple manner.

In the preferred embodiment, the invention provides a process for the production of a semiconductor component, wherein a polymeric gate dielectric layer (12) is structured in the absence of a resist solely by at least one imprint die (20) and, before and/or after the structuring by means of the imprint die (20), the polymer layer is cured and/or crosslinked, said curing and/or crosslinking being induced thermally and/or being induced by light. It is therefore possible to produce semiconductor circuits in a particularly simple manner.

Accordingly, a polymeric gate dielectric layer (e.g., an OFET) is structured in the absence of a resist solely by at least one imprint die in which the gate dielectric itself is directly structured.

Here, the structuring is effected solely by the imprint die and without using a resist, so that simple and rapid production of structures is achievable. The polymer layer is mechanically shaped by the imprint die, in particular slightly impressed. Before and/or after the structuring by means of an imprint die, the polymer layer is cured and/or crosslinked, the curing and/or crosslinking being induced thermally and/or being induced by light.

Particularly in the case of very small structures having thin gate dielectric layers, this combination of process steps is advantageous.

It is particularly advantageous if an imprint die is used for the production of at least one contact hole. These contact holes have a geometry which can be produced in a simple manner by an em bossing process according to the invention.

After structuring of the polymer layer by the imprint die, the base of the depression caused by the imprint die is advantageously processed by means of an etching step. Since the polymer layer is much thinner due to the depression, the polymer layer is first etched away at this point so that a contact hole is formed. This serves for minimizing the contact resistance. The surrounding polymer layer which is not depressed persists, apart from the etching loss. It is also possible thereby to remove polymer residues from the base of the contact hole. Such etching takes only a very short time in comparison with etching of a structure. It may be advantageous to carry out this etching until the polymer layer has reached a predetermined layer thickness.

In an advantageous embodiment of the invention, the polymer layer is applied to a substrate by spin coating, spraying on and/or immersion.

For the production of a field effect transistor, it is advantageous if the polymer layer is arranged as a dielectric layer on a first conducting layer and at least one contact hole for the production of a plated-through hole is covered by a second conducting layer.

It is also advantageous if an organic semiconductor layer for the production of an organic field effect transistor arrangement is arranged above the second conducting layer and the polymeric dielectric layer.

Systems comprising integrated circuits based on organic field effect transistors (OFET) constitute a promising technology in the mass application sector of economical electronics. A field effect transistor is considered to be organic particularly if the semiconducting layer is produced from an organic material.

Since it is possible to build up complex circuits using OFETs, there are numerous potential applications. Thus, for example, the introduction of RF-ID (RF-ID: radio frequency identification) systems based on this technology is considered as a potential replacement for the bar code, which is susceptible to faults and can be used only in direct visual contact with the scanner.

In particular, circuits on flexible substrates, which can be produced in large quantities in roll-to-roll processes, are of interest here.

Due to the thermal distortion of most suitable economical substrates (e.g. polyethylene terephthalate (PET), polyethylene naphthalate (PEN)), there is an upper temperature limit of 130-150° C. for the production of such flexible substrates. Under certain preconditions, for example, a thermal pretreatment of the substrate, this temperature limit can be increased to 200° C. but with the restriction that, although the distortion of the substrate is reduced, it is not prevented.

A critical process step in the case of electronic components is the deposition of the gate dielectric layer of an OFET. The quality of the dielectrics in OFETs has to meet very high requirements with regard to the thermal, chemical, mechanical and electrical properties.

Silicon dioxide (SiO₂) is currently the most frequently used gate dielectric in OFETs, based on the wide availability in semiconductor technology. Thus, transistor structures in which a doped silicon wafer serves as the gate electrode, and SiO₂ thermally grown thereon forms the gate dielectric are described. This SiO₂ is produced at temperatures of about 800-1000° C. Other processes (e.g., CVD) for the deposition of SiO₂ on various substrates likewise operate at temperatures above 400° C. A group at Penn State University has developed a process (ion beam sputtering), which makes it possible to deposit a high-quality SiO₂ at a process temperature of 80° C. This is described in the articles by C. D. Sheraw, J. A. Nichols, D. J. Gunlach, J. R. Huang, C. C. Kuo, H. Klauk, T. N. Jackson, M. G. Kane, J. Campi, F. P. Cuomo and B. K. Greening, Techn. Dig. -lot. Electron Devices Meet., 619 (2000), and C. D. Sheraw, L. Zhou, J. R. Huang, D. J. Gundlach, T. N. Jackson, M. G. Kane, I. G. Hili, M. S. Hammond, J. Campi, B. K. Greening, J. Francl and J. West, Appl. Phys. Lett. 80, 1088 (2002), each of which is incorporated herein by reference.

However, the high process costs and the low throughput are disadvantageous here for mass-produced products.

It is also known that inorganic nitrides, such as, for example, SiN_{x′}, TaNₓ, can be used. Similarly to the preparation of inorganic oxides, the deposits of inorganic nitrides require high temperatures or high process costs. This is described, for example, in the article by B. K. Crone, A. Dodabalapur, R. Sarpeshkar, R. W. Filas, Y. Y. Lin, Z. Bao, J. H. O'Neill, W. Li and H. E. Katz, J. Appl. Phys. 89, 5125 (2001), which is incorporated herein by reference.

It is also known that hybrid solutions (spin on glass) can be used. Organic siloxanes, which can be prepared from a solution and can be converted into “glass-like” layers by thermal conversion were described. The conversion into SiO₂ is effected either at high temperatures (about 400° C.) or takes place only partly, which results in a reduced transistor quality (in this context, cf. the article by Z. Bao, V. Kuck, J. A. Rogers and M. A. Paczkowski, Adv. Funct. Mater., 12, 526 (2002), which is incorporated herein by reference.

In addition, organic polymers, such as, for example, poly-4-vinylphenol (PVP), poly-4-vinylphenol-co-2-hydroxyethyl methacrylate or polyimide (PI), have already been used. These polymers are distinguished by their comparatively simple processibility. Thus, they can be used, for example, from a solution for spin coating or printing. The outstanding dielectric properties of such materials have already been demonstrated (cf. article by H. Klauk, M. Halik, U. Zschieschang, G. Schmid, W. Radlik and W. Weber, J. Appl. Phys., in press, scheduled to appear in vol. 92, no. 10 (November 2002), which is incorporated herein by reference).

It has also already been possible to demonstrate applications in ICs, the required chemical and mechanical stabilities of the dielectric layers for the structuring thereof and the structuring of the subsequent source-drain layer having been achieved by crosslinking of the polymers (cf. article by M. Halik, H. Klauk, U. Zschieschang, T. Kriem, G. Schmid and W. Radlik, Appl. Phys. Lett., 81, 289 (2002)).

However, this crosslinking is effected at temperatures of 200° C., which is problematic for the production of flexible substrates having a large area.

The process is advantageously carried out using the following polymer blends:
a) 100 parts of at least one crosslinkable base polymer,
b) from 10 to 20 parts of at least one electrophilic crosslinking component,
c) from 1 to 10 parts of at least one thermal acid catalyst which generates an activating proton at temperatures of 100-150° C., and
d) at least one solvent.

The integrated circuits produced in this manner are in particular OFETs having organic layers, which have outstanding dielectric properties. Due to the specific polymer formulation used, the integrated circuits can be produced in a simple manner at low temperatures (up to 150° C.). This polymer formulation can also be used in principle in combination with other electronic components.

It is advantageous if at least one base polymer is a phenol-containing polymer or copolymer, in particular poly-4-vinylphenol, poly-4-vinylphenol-co-2-hydroxyethyl methacrylate or poly-4-vinylphenol-co-methyl methacrylate.

Advantageously, at least one electrophilic crosslinking component is a di- or tribenzyl alcohol compound, in particular 4-hydroxymethylbenzyl alcohol.

It is advantageous if at least one crosslinking component has one of the following structures:

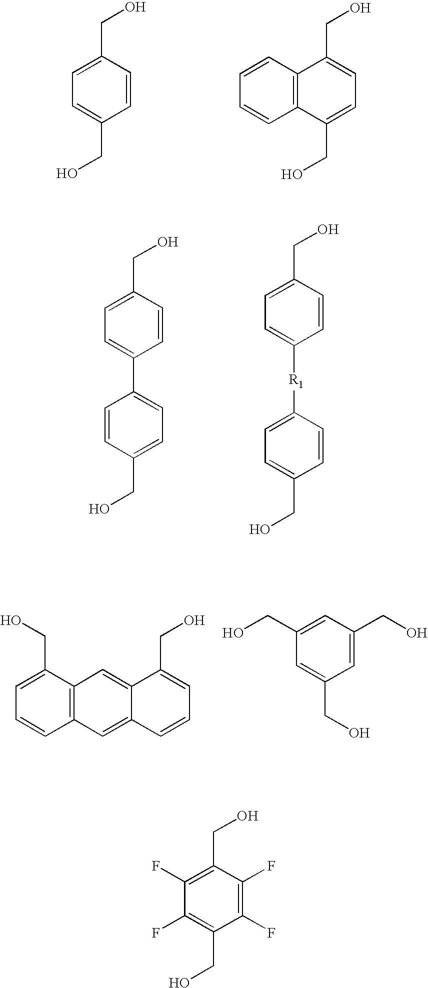

The following is true for R₁: —O—, —S—, —SO₂—, —S₂—, —(CH₂)—, in which x=1-10, and additionally:

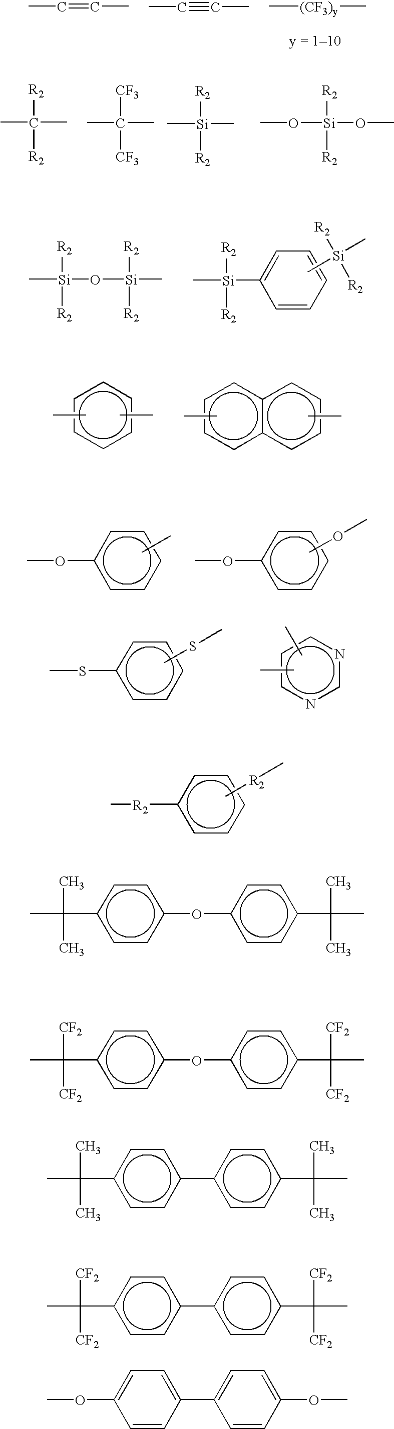

The following is true for R₂: alkyl having 1 to 10 carbon atoms or aryl

At least one sulfonic acid, in particular 4-toluenesulfonic acid, is advantageously used as the thermal acid catalyst, since this is capable of transferring a proton to the hydroxyl group of a benzyl alcohol at below 150° C.

Advantageous solvents are an alcohol, in particular n-butanol, propylene glycol monomethyl ethyl acetate (PGMEA), dioxane, N-methylpyrrolidone (NMP), γ-butyrolactone, xylene or a mixture.

For good processibility, it is advantageous if the proportion of base polymer, crosslinking component and acid generator is a proportion between 5 and 20% by mass.

A further embodiment of the process includes the following steps:
a) a polymer formulation is applied to a substrate, in particular having a prestructured gate electrode, and then
b) a crosslinking reaction for the formation of the gate dielectric layer is carried out at between 100 and 150° C.

For the production of an OFET, at least one further structuring for producing the OFET is then advantageously carried out.

Advantageously, the application of the polymer formulation is effected by spin coating, printing or spraying.

The crosslinking reaction is advantageously effected under an inert gas atmosphere, in particular an N₂ atmosphere.

After the application of the polymer formulation and the production of the polymer film, it is advantageous to carry out drying, in particular at 100° C.

For the production of the OFET, it is then advantageous to apply a source-drain layer to the gate dielectric layer.

Finally, it is advantageous if an active layer for the formation of an OFET, in particular including the semiconducting pentacene, is applied to the source-drain layer. Advantageously, a passivating layer is arranged on the active layer.

Alternatively, it is possible to produce a polymeric dielectric layer by means of a photo acid generator.

In one embodiment the following polymer formulation is used for the polymeric dielectric layer:
a) 100 parts of at least one crosslinkable base polymer,
b) from 10 to 20 parts of at least one di- or tribenzyl alcohol compound as the electrophilic crosslinking component,
c) from 0.2 to 10 parts of at least one photo acid generator, and
d) at least one solvent.

It is advantageous if at least one base polymer is a phenol-containing polymer or copolymer, in particular poly-4-vinylphenol, poly-4-vinylphenol-co-2-hydroxyethyl methacrylate or poly-4-vinylphenol-co-methyl methacrylate.

Advantageously, at least one di- or tribenzyl alcohol compound as the electrophilic crosslinking component is 4-hydroxymethylbenzyl alcohol.

It is advantageous if at least one of the crosslinking components described above is used.

It is advantageous to use, as the photo acid generator, at least one compound which, on exposure to UV light, generates a photo acid for transferring a proton to the hydroxyl group of a benzyl alcohol, in particular a sulfonium or an iodonium salt.

Advantageous solvents are an alcohol, in particular n-butanol, propylene glycol monomethyl ether acetate (PGMEA), dioxane, N-methylpyrrolidone (NMP), γ-butyrolactone, xylene or a mixture.

For good processibility, it is advantageous if the proportion of base polymer, crosslinking component and photo acid generator is a proportion between 5 and 20% by mass.

Advantageously,
a) a polymer formulation is applied to a substrate, in particular including a prestructured gate electrode, and then
b) a photo-induced crosslinking reaction for the formation of the gate dielectric layer is carried out.

For the production of an OFET, advantageously at least one further structuring for producing the OFET is then carried out.

The photoinduced crosslinking reaction is advantageously initiated by exposure to UV radiation. It is particularly advantageous if, after the exposure, a heating step, in particular a post exposure bake, is effected. It is advantageous if the temperature in the heating step is not more than 140° C., in particular 100° C. After the post exposure bake (PEB), it is advantageous if at least one further structuring for producing the OFET is effected.

The application of the polymer formulation is preferably effected by spin coating, printing or spraying.

The crosslinking reaction is advantageously effected under an inert gas atmosphere, in particular an N₂ atmosphere. After the application of the polymer formulation and the production of the polymer film, it is advantageous to carry out drying, in particular at 100° C.

For the production of the OFET, it is then advantageous to apply a source-drain layer to the gate dielectric layer.

Finally, it is advantageous if an active layer for the formation of an OFET, in particular including the semiconducting pentacene, is applied to the source-drain layer. A passivating layer is advantageously arranged on the active layer.

### BRIEF DESCRIPTION OF THE DRAWINGS

The invention is explained in more detail below for a plurality of embodiments with reference to the figures of the drawings.

FIG. 1 shows a schematic diagram of an integrated circuit with through-hole plating according to the prior art;

FIGS. 2A to 2F show schematic diagrams of process steps of an embodiment of the process according to the invention (relating to section X from FIG. 1);

FIG. 3 shows a schematic diagram of an organic field effect transistor;

FIG. 4 shows an example of a crosslinking reaction of a polymeric gate dielectric inlcuding PVP and 4-hydroxymethylbenzyl alcohol as a crosslinking agent;

FIG. 5a shows a family of output characteristics of an OFET comprising an electrophilically crosslinked gate dielectric;

FIG. 5b shows a family of transmission characteristics of an OFET comprising an electrophilically crosslinked gate dielectric;

FIG. 6 shows a trace of an oscilloscope image;

FIG. 7 shows a schematic diagram of a further embodiment of an organic field effect transistor;

FIG. 8 shows an example of a photoinduced crosslinking reaction of a polymeric gate dielectric including PVP and 4-hydroxymethylbenzyl alcohol as a crosslinking agent;

FIG. 9A shows a family of output characteristics of an OFET inlcuding an electrophilically crosslinked gate dielectric; and

FIG. 9B shows a family of transmission characteristics of an OFET including an electrophilically crosslinked gate dielectric.

The following list of reference symbols can be used in conjunction with the figures:

| | |
|---|---|
| 1 | Substrate |
| 2 | Gate electrode |
| 3 | Gate dielectric layer |
| 4a | Drain layer |
| 4b | Source layer |
| 5 | Active layer |
| 6 | Passivating layer |
| 7 | Interconnect layer |
| 10 | Substrate |
| 11a, b, c | First conducting layer (metallization layer) |
| 12 | Polymer layer (dielectric layer) |
| 13a, b, c | Second conducting layer (metallization layer) |
| 14 | Organic semiconductor layer |
| 20 | Imprint die |
| 30 | Plasma etching |
| 40 | Contact hole |

### DETAILED DESCRIPTION OF ILLUSTRATIVE EMBODIMENTS

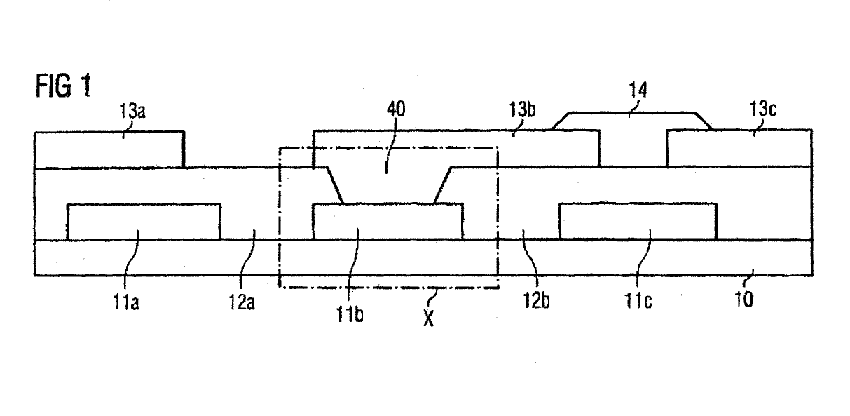

FIG. 1 shows a schematic cross section through a part of an integrated circuit comprising two conducting layers, namely a first conducting layer 11a, 11b, 11c and a second conducting layer 13a, 13b, 13c present above this. Here, the conducting layers are in the form of metallization planes.

A gate dielectric layer 12a, 12b and an organic semiconductor layer 14 are arranged above the first conducting layer 11a, 11b, 11c.

In order to realize a plated-through hole (“via”), a contact hole 40 must be opened in a targeted manner in the gate dielectric layer 12a, 12b.

An organic transistor is arranged in the right part of the circuit, consisting of a gate electrode (realized in the first conducting layer 11b, 11c), the gate dielectric 12b, two contacts in the second conducting layer 13b, 13c and the organic semiconductor layer 14.

A plated-through hole (“via”) is arranged in the middle of the circuit. By opening the contact hole 40, an electrical connection is made between the two conducting layers 11, 13. At an electrically insulating intersection of two conductor tracks (“crossover”) in the left part of the circuit, the gate dielectric layer 12a performs the function of insulating the two conducting layers 11, 13.

According to the preferred embodiment of the invention, an embodiment of the process for realizing plated-through holes (contact holes 40) is used in the production of integrated circuits having polymeric gate dielectrics.

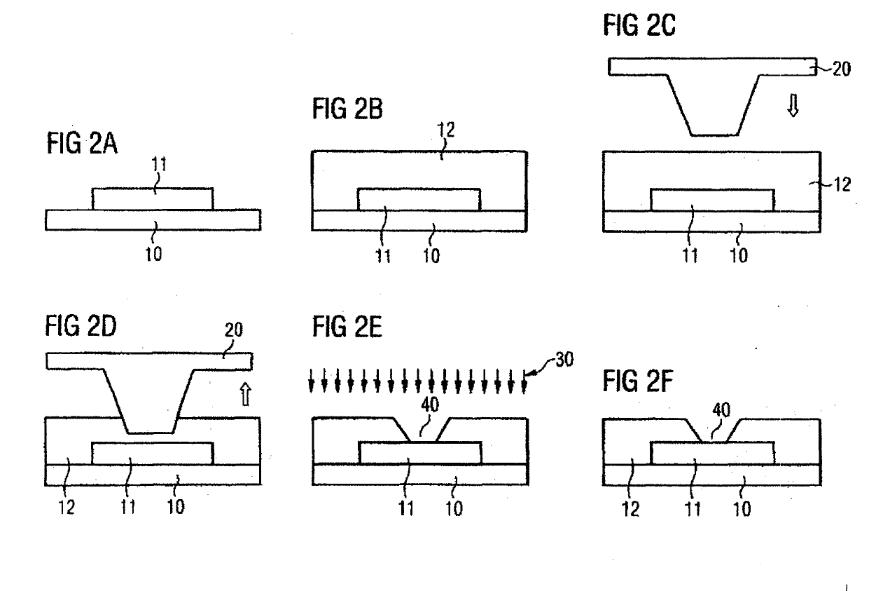

While, in the known imprint lithography, the polymer layer 12 plays the role of an etch resist, which is removed again after transfer of the structure to the substrate underneath is complete, in the process according to the invention the desired structures are transferred by means of the die directly and without a resist into the gate dielectric layer. Thus, the structure in the polymer layer 12 is produced in the vertical direction solely by an imprint die 20 (as shown in FIG. 2).

This is explained in more detail in relation to FIGS. 2A to 2F, FIGS. 2A to 2F show the details of the region which is denoted by X in FIG. 1, i.e., in the immediate vicinity of the contact hole 40.

In order to open the contact hole 40 down to the lower conducting layer 11, a short plasma etching step may be necessary after curing of the polymer. By mechanical molding of the polymer layer 12, the latter is thinned in a targeted manner in an area, so that an etching step exposes the first conducting layer 11 here before the surrounding polymer layer 12 is etched away. The remaining polymer layer 12 can then be used in the further production of the semiconductor component.

However, according to the embodiment of the process according to the invention, the total depth of the plated-through hole need not be completely etched since the structure formation by the imprint process is sufficient under certain circumstances.

By means of this plasma etching step, the surface of the first, lower conducting layer 11 is exposed in the regions of the contact holes 40, and any polymer residues remaining in the contact hole 40 are removed. This guarantees a contact resistance, as small as possible, between upper and lower conducting layer 13, 11. During the plasma etching, a reduction in the layer thickness of the polymer layer 12 also occurs in the areas outside the plated-through holes as a result of material ablation, so that the plasma etching step can be used for establishing the thickness of the dielectric polymer layer 12 in a targeted manner.

FIGS. 2A to 2F show individual steps of an embodiment of the process according to the invention.

As shown in FIG. 2a, a first conducting layer 11 is applied to a substrate 10 (also shown in FIG. 1). The first conducting layer 11 may comprise, for example, of aluminum, titanium, nickel, gold or a conductive polymer, such as, for example, polyaniline or PEDOT:PSS.

Referring to FIG. 2b, the polymer layer 12 is then applied as a gate dielectric layer and is fixed (generally thermally). The fixing serves for expelling the solvent residues from the polymer layer 12. The polymer layer 12 can be applied from a suitable solution by spin coating, dip coating or spray coating. The fixing can be effected on a hotplate, by means of a hot roll or in a drying oven.

Suitable polymers are in principle all polymers which are suitable as a dielectric layer for organic field effect transistors.

As shown in FIG. 2c, The transfer of the desired structures (for example contact hole 40) into the polymer layer 12 is effected by means of the imprint die 20, which was coated beforehand with an anti-adhesion layer, not shown here, (for example, a monolayer of an alkylsilane). Here, the imprint die 20 has the shape of a truncated cone so that it can be removed again from the polymer layer 12 without difficulties. In principle, other geometries are also possible for the imprint die 20.

The fixing of the structures produced by means of the die in the polymer layer 12 can be effected, depending on the polymer, by a temperature-induced (e.g., cooling) or a light-induced (e.g., UV light) curing or crosslinking step, as shown in FIG. 2D. In this step, the polymer layer 12 is converted into the final chemical form which, compared with the originally plastic form of the polymer, is more dimensionally stable and advantageously more resistant to the final plasma etching step (plasma etching 30 in FIG. 2E).

As shown in FIG. 2e, after removal of the imprint die 20, the opening of the resulting contact hole 40 by a plasma etching step (for example using an oxygen plasma) and cleaning of the surface of the first conducting plane 11 in the region of the contact holes 40 are effected. Optionally as shown in FIG. 2f, the etching can be effected beyond the complete opening of the contact holes 40, provided that the desired layer thickness of the gate dielectric layer 12 (i.e., of the polymer layer) is established by material ablation.

The polymer layer 12 thus does not serve primarily as an etch resist but as an active layer, namely as a gate dielectric layer in the further production of a semiconductor component.

After the production of the plated-through hole, the further production of the circuit with the second conducting layer 13 and the organic semiconductor layer 14, as shown in FIG. 1, is effected for the production of an organic field effect transistor. Accordingly, the second conducting layer 13 and the organic semiconductor layer 14 are built up above the layers.

The first embodiment of the invention has been described here with reference to the production of an organic field effect transistor. In principle, however, it is also possible to produce other circuits by the process according to other embodiments of the invention.

The temperature- and/or light-induced curing or crosslinking step, as shown in FIG. 2D, is not absolutely essential, provided that the gate dielectric layer 12 comprising polymer also reproduces the structures in uncrosslinked form and can also be etched in uncrosslinked form so that, after complete opening of the contact holes 40, a sufficiently thick polymer layer 12 is maintained as a dielectric. This relates in particular to silicon-containing polymers which, under the action of oxygen plasma, form an SiO₂-like surface which is very stable to etching in comparison with purely organic polymers.

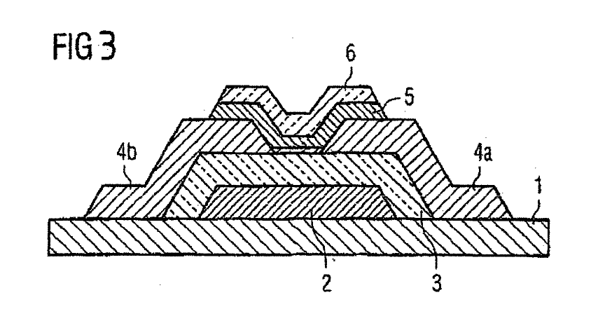

FIGS. 3 to 6 describe embodiments of the imprint process according to the invention in relation to a polymer formulation which is prepared by means of a thermal acid catalyst.

OFETs are electronic components which consist of a plurality of layers, all of which have been structured, in order to generate integrated circuits by connections of individual layers. FIG. 3 shows the fundamental structure of such a transistor in a bottom contact architecture.

A gate electrode 2, which is covered by a gate dielectric layer 3, which in this case is in the form of a polymer gate dielectric layer, is arranged on a substrate 1. As will be explained later, in an embodiment of the process according to the invention the substrate 1 with the gate electrode 2 already arranged thereon constitutes the starting material on which the gate dielectric layer 3 is applied. A drain layer 4a and a source layer 4b, both of which are connected to a active semiconducting layer 5, are arranged on the gate dielectric layer 3. A passivating layer 6 is arranged above the active semiconducting layer 5.

The deposition and processing of the gate dielectric layer 3 are decisive for that embodiment of the invention which is described here.

The circuits according to the embodiments of the present invention and the production thereof solve the problem of the provision of OFETs having gate dielectric layers, in particular with organic ICs having outstanding mechanical, chemical and electrical properties in combination with low process temperatures.

An OFET has a dielectric layer which, in this embodiment, can be produced from a mixture (polymer formulation) comprising in principle four components: a base polymer, a crosslinking component, a thermal acid generator and a solvent. An embodiment of the circuit according to the invention, which is mentioned here by way of example, has a polymer formulation comprising the following components:
a) PVP as the crosslinkable base polymer,
b) 4-hydroxymethylbenzyl alcohol as an electrophilic crosslinking component,
c) 4-toluenesulfonic acid, which generates an activating proton at temperatures of 100-150° C., as the acid catalyst, and
d) e.g., alcohols, PGMEA as the solvent.

This polymer formulation is applied to a correspondingly prepared substrate 1 (gate electrodes 2 have already been defined on the substrate 1). The polymer formulation can be applied, for example, by printing, spin coating or spray coating. By subsequent drying at moderate temperatures (about 100° C.), the polymer formulation is fixed on the substrate 1 and then converted into its final structure in a thermal crosslinking step.

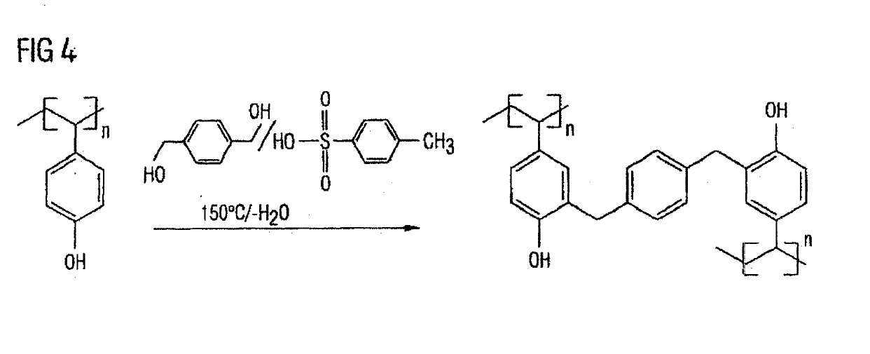

FIG. 4 shows, in a schematic manner, how PVP is crosslinked with 4-hydroxymethylbenzyl alcohol at a temperature of 150° C. with elimination of water. Alternatively, the compounds shown below can also be used as electrophilic crosslinking agents:

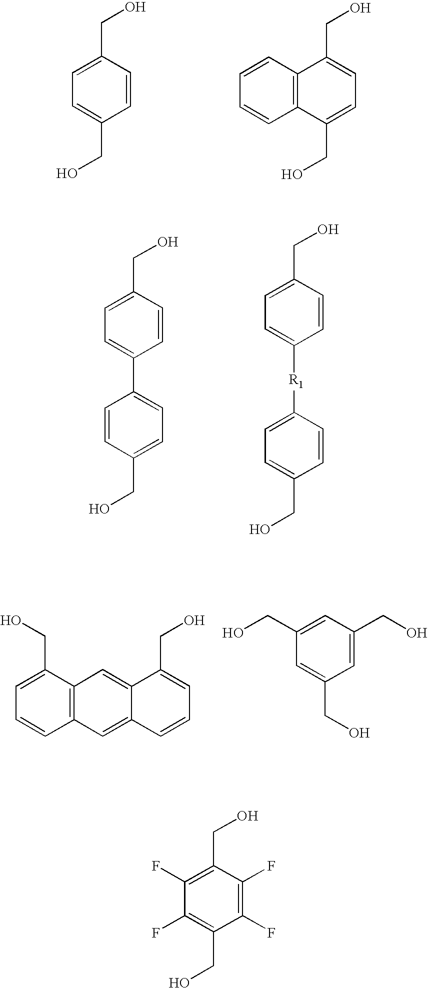

The following is true for R₁: —O—, —S—, —SO₂—, —S₂—, —(CH₂)ₓ—, in which x=1-10, and additionally:

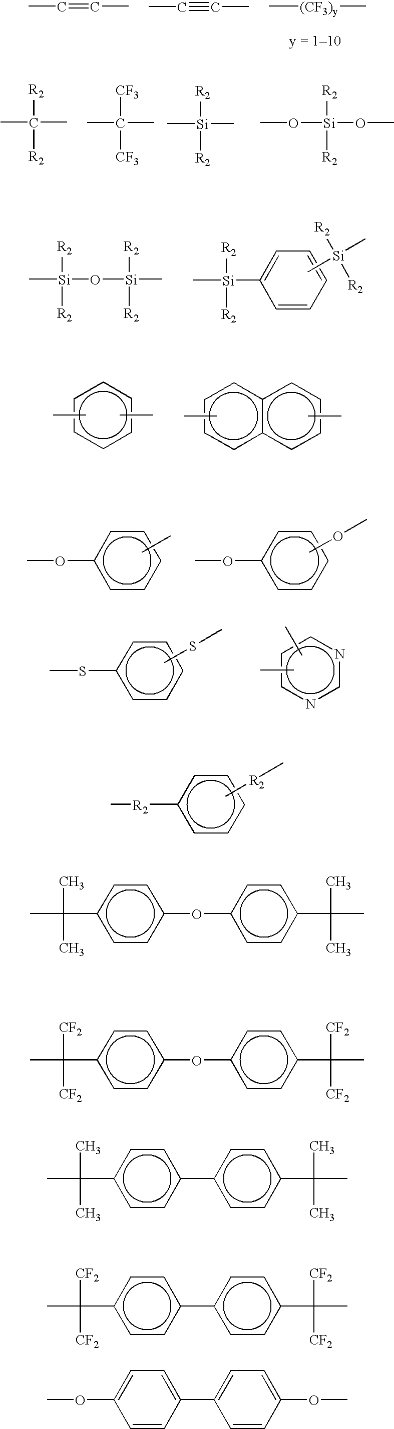

The following is true for R₂: alkyl having 1 to 10 carbon atoms or aryl

Here, the decisive step for the production of the gate dielectric layers 3 having the required properties is this crosslinking reaction and the initiation thereof at temperatures which are not critical for the substrate 1. These are temperatures of 20° C. to not more than 150° C.

The use of the process reduces the required crosslinking temperature by more than 50° C. compared with the methods known to date (cf. article by Halik et al. (2002)).

The base polymer determines the fundamental properties of the gate dielectric layer 3. Suitable base polymers are in principle all phenol-containing polymers and copolymers thereof, such as, for example, poly-4-vinylphenol, poly-4-vinylphenol-co-2-hydroxyethyl methacrylate or poly-4-vinylphenol-co-methyl methacrylate.

By the choice of the crosslinking components and the concentration thereof in the polymer formulation, the mechanical properties of the polymer layer and the resistance to chemicals can be decisively controlled.

By the choice of the thermal acid catalysts, the temperature of the initiation of the crosslinking reaction can be controlled.

The choice of the solvent determines the film formation properties of the formulation.

Two polymer formulations which differ only in the proportion of the crosslinking agent are described below as examples.

Formulation 1 is a 10% strength solution in propylene glycol monomethyl ether acetate (PGMEA). 100 parts of base polymer, 10 parts of crosslinking agent and 2.5 parts of acid generator are present.

A mixture of 2 g of PVP (MW about 20 000) as base polymer and 200 mg of 4-hydroxymethylbenzyl alcohol as crosslinking agent is dissolved in 20.5 g of PGMEA as solvent on a shaking apparatus e.g., for about 3 hours.

Thereafter, 50 mg of 4-toluenesulfonic acid as an acid generator are added and the total solution is shaken for a further hour. Before use, the polymer solution is filtered through a 0.2 μm filter.

Formulation 2 is a 10% strength solution in PGMEA. 100 parts of base polymer, 20 parts of crosslinking agent and 2.5 parts of acid generator are present. The proportion of the crosslinking agent is therefore twice as high as in formulation 1. A mixture of 2 g of PVP (MW about 20 000) of base polymer and 400 mg of 4-hydroxymethylbenzyl alcohol as a crosslinking agent is dissolved in 20.5 g of PGMEA as a solvent on a shaking apparatus e.g., also for about 3 hours. Thereafter, 50 mg of 4-toluenesulfonic acid as an acid generator are added and the total solution is shaken for a further hour. Before use, the polymer solution is filtered through a 0.2 μm filter.

Film preparation will now be discussed. 2 ml of the formulation 1 were applied by means of a spin coater at 4000 rpm for 22 seconds to a prepared substrate (PEN (polyethylene naphthalate) having Ti gate structures). Drying is then effected at 100° C. for 2 minutes on a hotplate. The crosslinking reaction is effected at 150° C. in an oven under a 400 mbar N₂ atmosphere. The film preparation for formulation 2 is effected analogously.

Structuring of the gate dielectric layer will now be discussed. A photoresist is applied (S 1813; 3000 rpm; 30 s) to the crosslinked polymer layer (gate dielectric layer 3) and dried at 100° C. for 2 minutes. The subsequent contact holes are then defined by means of exposure to light and development of the photoresist. The opening of the contact hole is effected by means of oxygen plasma. Perform this twice for 45 seconds at 100 W.

The source-drain layer 4 is then deposited and structured by standard methods, for example, 30 nm Au applied thermally by vapor deposition, photolithographic structuring and wet chemical etching with I₂/KI solution.

The layer thickness of the gate dielectric layers 3 is 210 nm for formulation 1. The roughness of the layer is 0.5 nm on 50 μm.

The layer thickness of the gate dielectric layers 3 is 230 nm for formulation 2. The roughness of the layer is 0.6 nm on 50 μm.

The transistors or circuits are completed by applying the active component 5 (in this case pentacene) thermally by vapor deposition. Apart from the passivating layer 6, the structure of an OFET according to FIG. 1 is thus produced.

Here, embodiments for a polymer formulation and the use thereof for the production of gate dielectric layers 3 at low temperatures for use in integrated circuits based on OFETs are described. These gate dielectric layers 3 are distinguished by outstanding thermal, chemical, mechanical and electrical properties in addition to the low process temperature for the production of the layers.

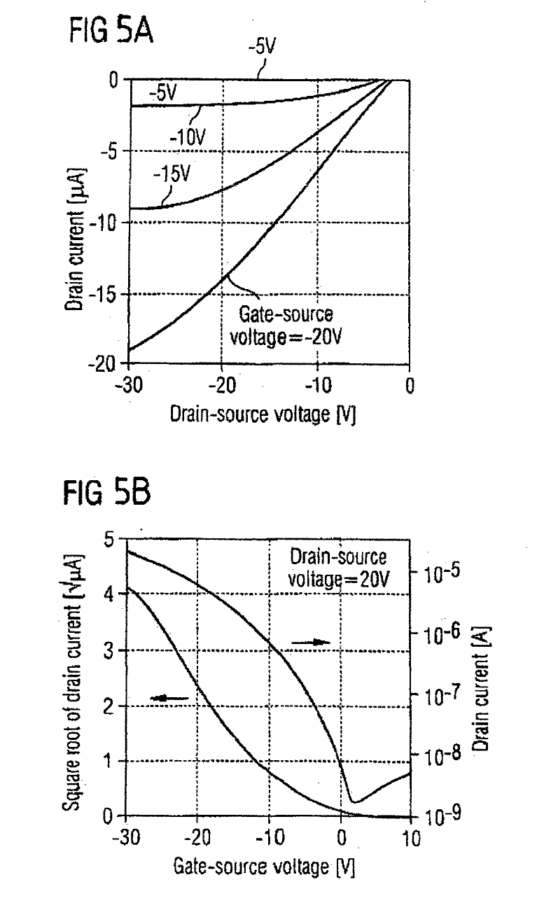

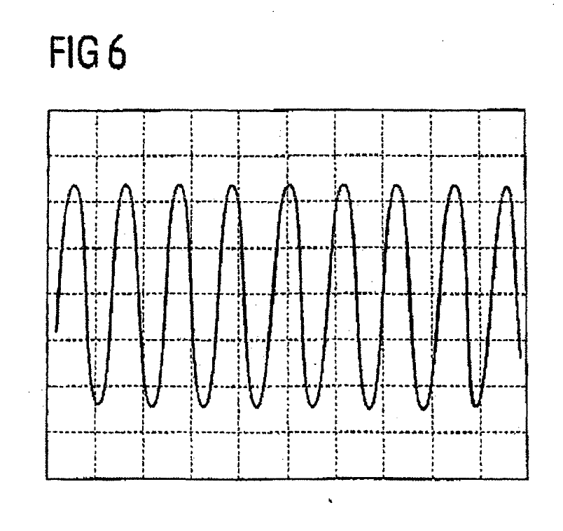

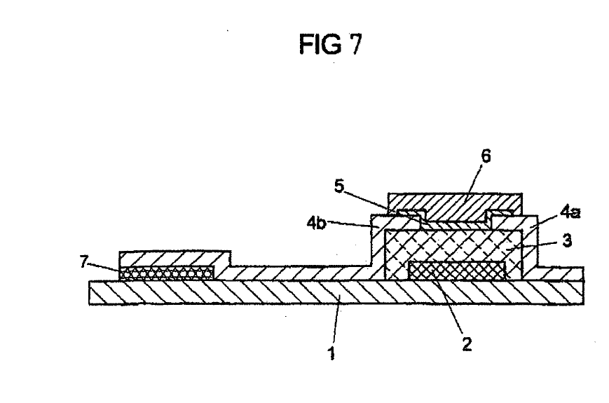

FIG. 5A shows a family of output characteristics of a pentacene OFET comprising an electrophilically crosslinked gate dielectric. FIG. 5B shows, for the same structure, the transmission characteristics of an OFET (μ=0.5 cm²/Vs, on/off ratio=10⁴). FIG. 6 reproduces a trace of an oscilloscope diagram. The characteristic of a 5-stage ring oscillator is shown, the ring oscillator operates with a signal lag of 120 μsec per stage. crosslinking are described in FIGS. 7 to 10. FIG. 7 corresponds substantially to FIG. 3, so reference is made to the above description. The source layer 4b produces a connection to an interconnect layer 7.

The deposition and processing of the gate dielectric layer 3, which is in the form of a polymeric gate dielectric layer, are decisive for that embodiment of the invention which is described here.

The embodiments solve the problem of providing OFETs comprising gate dielectric layers, in particular with organic ICs having outstanding mechanical, chemical and electrical properties in combination with low process temperatures.

An OFET has a dielectric layer, which can be produced from a mixture (polymer formulation) comprising in principle four components: a base polymer, a crosslinking component, a photo acid generator and a solvent. An embodiment of the circuit according to the invention which is mentioned here by way of example has a polymer formulation comprising the following components
a) PVP as the crosslinkable base polymer,
b) 4-hydroxymethylbenzyl alcohol as an electrophilic crosslinking component,
c) triphenylsulfonium hexaflate as the photo acid generator (PAG), and
d) e.g. alcohols, PGMEA as the solvent.

This polymer formulation is applied to a correspondingly prepared substrate 1 (gate structures 2 have already been defined on the substrate 1). The polymer formulation can be moderate temperatures (about 100° C.), the polymer formulation is fixed on the substrate.

Thereafter, an exposure step using UV light is effected, the wavelength and the duration of the UV irradiation are dependent on the photo acid generator used. A photo acid, which initiates a crosslinking reaction in a subsequent heating step (not more than 140° C., post exposure bake (PEB)), is generated from the photo acid generator.

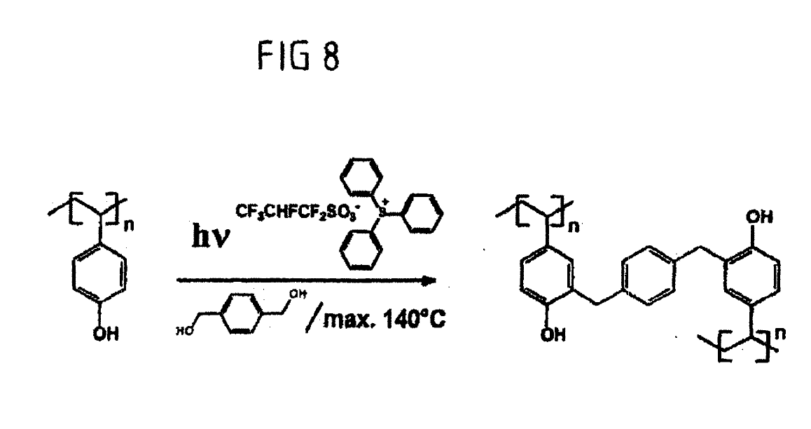

FIG. 8 shows the photoinduced electrophilic crosslinking reaction of a polymeric gate dielectric for PVP by way of example with 4-hydroxymethylbenzyl alcohol as the crosslinking component. The photo acid generator used is triphenylsulfonium hexaflate.

As a result of the photochemically induced crosslinking reaction, solubility differences are produced between crosslinked and uncrosslinked material. By using masks, a definition of exposed and unexposed parts is possible thereby, which can be used for structuring the gate dielectric layer 3.

The use of the process reduces the required crosslinking temperature by more than 60° C. compared with the methods known to date (cf. article by Halik et al. (2002)). The temperatures used are not critical for the substrate 1.

The base polymer determines the fundamental properties of the gate dielectric layer 3. Suitable base polymers are in principle all phenol-containing polymers and copolymers thereof, such as, for example, poly-4-vinylphenol, poly-4-vinylphenol-co-2-hydroxyethyl methacrylate or poly-4-vinylphenol-co-methyl methacrylate.

By the choice of the crosslinking component and the concentration thereof in the polymer formulation, the mechanical properties of the polymer layer and the resistance to chemicals can be decisively controlled.

By the choice of the photo acid generator, wavelength and exposure dose, the initiation of the crosslinking reaction can be controlled. The temperature of the post exposure bake (PEB) determines the duration of the crosslinking step since this is determined substantially by the diffusion of the photo generated acid.

The choice of the solvent determines the film formation properties of the formulation.

Two polymer formulations which differ only in the proportion of the crosslinking agent are described below as examples.

Formulation 1 is a 10% strength solution in propylene glycol monomethyl ether acetate (PGMEA). 100 parts of base polymer, 10 parts of a crosslinking agent and 2.5 parts of a photo acid generator are present.

A mixture of 2 g of PVP (MW about 20 000) as base polymer and 200 mg of 4-hydroxymethylbenzyl alcohol as a crosslinking agent is dissolved in 20.5 g of PGMEA as a solvent on a shaking apparatus e.g., for about 3 hours. Thereafter, 50 mg of triphenylsulfonium hexaflate as a photo acid generator are added and the total solution is shaken for a further hour. Before use, the polymer solution is filtered through a 0.2 μm filter.

Formulation 2 is a 10% strength solution in PGMEA. 100 parts of base polymer, 20 parts of crosslinking agent and 2.5 parts of photo acid generator are present. The proportion of crosslinking agent is therefore twice as high as in the formulation 1.

A mixture of 2 g of PVP (MW about 20 000) as base polymer and 400 mg of 4-hydroxymethylbenzyl alcohol as crosslinking agent is dissolved in 20.5 g of PGMEA as solvent on a shaking apparatus e.g., for about 3 hours. Thereafter, 50 mg of triphenylsulfonium hexaflate as a photo acid generator are added and the total solution is shaken for a further hour. Before use, the polymer solution is filtered through a 0.2 μm filter.

Film preparation will now be described. 2 ml of the formulation 1 were applied by means of a spin coater at 4000 rpm for 22 s to a prepared substrate (PEN (polyethylene naphthalate) having Ti gate structures). Thereafter, drying is effected at 100° C. for 2 min on a hotplate. The layer is then exposed at wavelength 365 nm, for a duration 30 seconds, the intensity of irradiation being 7 mW/cm². A post exposure bake is then effected at 140° C. in an oven under a 400 mbar N₂ atmosphere for 20 minutes. The film preparation for formulation 2 is effected analogously.

Structuring of the gate dielectric layer will now be described. The structuring is effected as stated in the examples, except that the crosslinked polymer layer (gate dielectric layer 3) is exposed using a bright field chromium mask, chrome on glass (COG). After the post exposure bake step, uncrosslinked dielectric (i.e., parts of the dielectric layer 3 which were not exposed to light) is dissolved away with acetone. The structured dielectric layer 3 remains in the exposed parts.

The source-drain layer 4A, 4B is then deposited and structured by standard methods, such as, for example, 30 nm Au applied thermally by vapor deposition, photolithographic structuring and wet chemical etching with I₂/KI solution.

The layer thickness of the gate dielectric layers 3 is 200 nm for formulation 1. The roughness of the layer is 0.7 nm on 50 μm.

The layer thickness of the gate dielectric layers is 210 nm for formulation 2. The roughness of the layer is 0.7 nm on 50 μm.

The transistors or circuits are completed by applying the active component 5 (in this case pentacene) thermally by vapor deposition. Except for the passivating layer 6, the structure of an OFET according to FIG. 7 is thus produced.

Here, embodiments for a polymer formulation and the use thereof for the production of gate dielectric layers 3 at low temperatures for use in integrated circuits based on OFETs are described. These gate dielectric layers 3 are distinguished by outstanding thermal, chemical, mechanical and electrical properties in addition to the low process temperature for the production thereof.

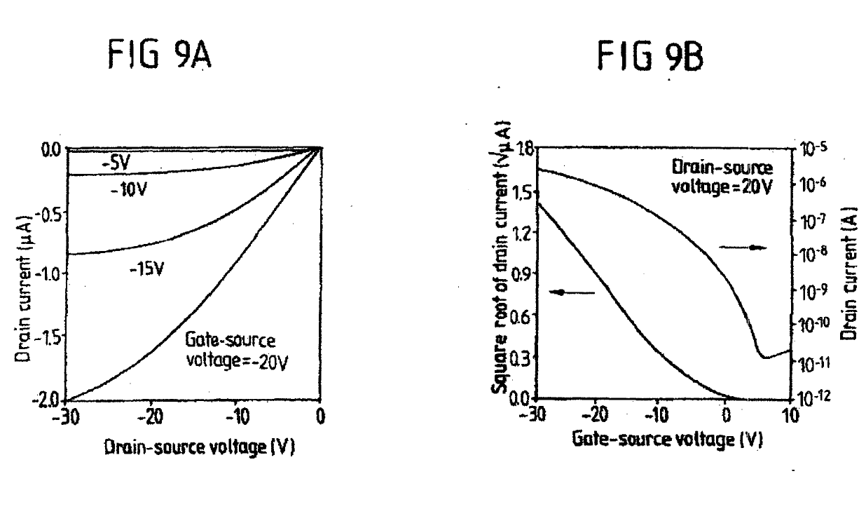

FIG. 9A shows a family of output characteristics of a pentacene OFET comprising an electrophilically crosslinked gate dielectric. FIG. 9B shows, for the same structure, the transmission characteristics of an OFET (μ=0.8 cm²/Vs, on/off ratio=10⁵).

1. An imprint lithography process for the production of a semiconductor component, the process comprising:
structuring a polymeric gate dielectric layer in the absence of a resist solely by at least one imprint die; and
curing and/or crosslinking the polymer layer, said curing and/or crosslinking being induced thermally and/or being induced by light, wherein the curing and/or crosslinking is performed before and/or after the structuring by the at least one imprint die.

2. The imprint lithography process as claimed in claim 1, wherein the at least one imprint die is used for the production of at least one contact hole.

3. The imprint lithography process as claimed in claim 2, wherein, after structuring of the polymeric gate dielectric layer by the imprint die, the bottom of the depression caused by the imprint die is processed by an etching step to expose a contact hole.

4. The imprint lithography process as claimed in claim 3, wherein the etching step for exposing the contact hole is continued until the polymeric gate dielectric layer has reached a predetermined layer thickness.

5. The imprint lithography process as claimed in claim 1, and further comprising applying the polymeric gate dielectric layer to a substrate by spin coating, spray coating and/or dip coating.

6. The imprint lithography process as claimed in claim 2, wherein the polymeric gate dielectric layer is arranged on a first conducting layer and at least one contact hole is covered by a second conducting layer.

7. The imprint lithography process as claimed in claim 6, and further comprising arranging an organic semiconductor layer for producing an organic field effect transistor arrangement above the second conducting layer and the polymeric gate dielectric layer.

8. The imprint lithography process as claimed in claim 1, wherein the polymeric gate dielectric layer is formed from:
a) 100 parts of at least one crosslinkable base polymer;
b) from 10 to 20 parts of at least one electrophilic crosslinking component;
c) from 1 to 10 parts of at least one thermal acid catalyst which generates an activating proton at temperatures of 100-150° C.; which are dissolved in at least one solvent.

9. The imprint lithography process as claimed in claim 8, wherein the at least one base polymer comprises a phenol-containing polymer or copolymer, the at least one base polymer being selected from the group consisting of poly-4-vinylphenol, poly-4-vinylphenol-co-2-hydroxyethyl methacrylate, and poly-4-vinylphenol-co-methyl methacrylate.

10. The imprint lithography process as claimed in claim 8, wherein the at least one thermal acid catalyst comprises a sulfonic acid.

11. The imprint lithography process as claimed in claim 8, wherein the at least one electrophilic crosslinking component comprises a di- or tribenzyl alcohol compound.

12. The imprint lithography process as claimed in claim 8, wherein at least one crosslinking component has one of the following structures:

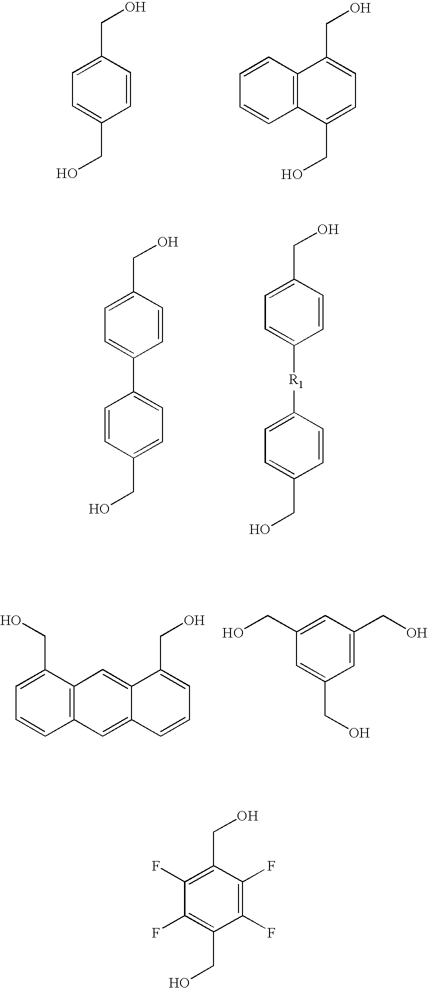

13. The imprint lithography process as claimed in claim 8, wherein the at least one solvent comprises an alcohol selected from the group consisting of n-butanol, propylene glycol monomethyl ether acetate (PGMEA), dioxane, N-methylpyrrolidone (NMP), γ-butyrolactone, and xylene, and mixtures thereof.

14. The imprint lithography process as claimed in claim 8, wherein a proportion of base polymer, crosslinking component and acid catalyst is from 5 to 20% by mass.

15. An imprint lithography process for the production of a semiconductor component, the process comprising:
applying a polymeric gate dielectric layer to a substrate, the substrate including a prestructured gate electrode, wherein the polymeric dielectric layer is formed from a) 100 parts of at least one crosslinkable base polymer, b) 10 to 20 parts of at least one electrophilic crosslinking component, and c) 1 to 10 parts of at least one thermal acid catalyst which generates an activating proton at temperatures of 100-150° C., dissolved in d) at least one solvent;
structuring a polymeric gate dielectric layer in the absence of a resist solely by at least one imprint die;
causing a crosslinking reaction in the gate dielectric layer, the crosslinking reaction being effected at from 100 to 150° C., wherein the crosslinking is performed before and/or after the structuring by the at least one imprint die.

16. The imprint lithography process as claimed in claim 15, and further comprising effecting at least one further structuring for producing an organic field effect transistor.

17. The imprint lithography process as claimed in claim 15, wherein applying a polymeric gate dielectric layer comprises applying the layer by spin coating, printing or spraying.

18. The imprint lithography process as claimed in claim 15, wherein the crosslinking reaction is effected under an inert gas atmosphere, comprising an N₂ atmosphere.

19. The imprint lithography process as claimed in claim 15, and further comprising drying the polymeric gate dielectric layer.

20. The imprint lithography process as claimed in claim 15, and further comprising applying a source-drain layer to the gate dielectric layer.

21. The imprint lithography process as claimed in claim 20, and further comprising applying an active layer for the formation of an OFET to the source-drain layer.

22. The imprint lithography process as claimed in claim 15, and further comprising arranging a passivating layer over the active layer.

23. The imprint lithography process as claimed in claim 15, wherein the polymeric dielectric layer is formed from:
a) 100 parts of at least one crosslinkable base polymer;
b) from 10 to 20 parts of at least one di- or tribenzyl alcohol compound as the electrophilic crosslinking component; and
c) from 2 to 10 parts of at least one photo acid generator.

24. The imprint lithography process as claimed in claim 23, wherein the at least one base polymer comprises a phenol-containing polymer or copolymer selected from the group consisting of poly-4-vinylphenol, poly-4-vinylphenol-co-2-hydroxyethyl methacrylate, and poly-4-vinylphenol-co-methyl methacrylate.

25. The imprint lithography process as claimed in claim 23, wherein the at least one di- or tribenzyl alcohol compound as an electrophilic crosslinking component comprises 4-hydroxymethylbenzyl alcohol.

26. The imprint lithography process as claimed in claim 23, wherein at least one crosslinking component has at least one of the following structures:

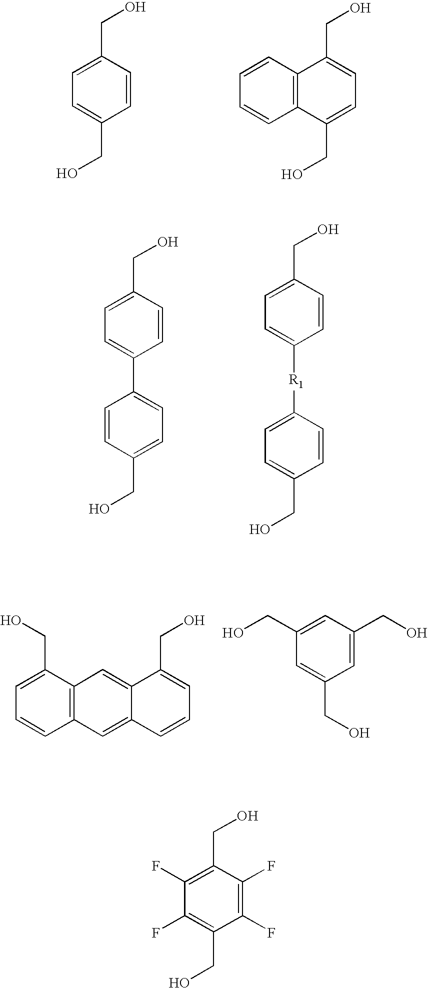

27. The imprint lithography process as claimed in claim 23, wherein the at least one photo acid generator comprises a compound which, on exposure to UV light, generates a photo acid for transferring a proton to the hydroxyl group of a benzyl alcohol.

28. The imprint lithography process as claimed in claim 27, wherein the at least one photo acid generator comprises a sulfonium or an iodonium salt.

29. The imprint lithography process as claimed in claim 23, wherein the at least one solvent comprises an alcohol selected from the group consisting of n-butanol, propylene glycol monomethyl ether acetate (PGMEA), dioxane, N-methylpyrrolidone (NMP), γ-butyrolactone and xylene and mixtures thereof.

30. The imprint lithography process as claimed in claim 23, wherein a proportion of base polymer, crosslinking component and photo acid generator is from 5 to 20% by mass.

31. An imprint lithography process for the production of a semiconductor component, the process comprising:
applying a polymeric gate dielectric layer to a substrate, the substrate including a prestructured gate electrode, wherein the polymeric dielectric layer is formed from a) 100 parts of at least one crosslinkable base polymer, b) from 10 to 20 parts of at least one di- or tribenzyl alcohol compound as an electrophilic crosslinking component, c) from 0.2 to 10 parts of at least one photo acid generator, dissolved in d) at least one solvent;
structuring a polymeric gate dielectric layer in the absence of a resist solely by at least one imprint die;
causing a photoinduced crosslinking reaction for the formation of crosslinked parts of the gate dielectric layer, the crosslinking reaction being performed before and/or after the structuring by the at least one imprint die.

32. The imprint lithography process as claimed in claim 31, wherein the photoinduced crosslinking reaction is initiated by exposure to UV radiation.

33. The imprint lithography process as claimed in claim 31, wherein, the photoinduced crossing reaction is initiated by exposure to light and wherein, after the exposure to light, a heating step is effected.

34. The imprint lithography process as claimed in claim 33, wherein the heating step is performed at a temperature of not more than 140° C.

35. The imprint lithography process as claimed in claim 31, wherein, after the post exposure bake (PEB), at least one further structuring for producing the OFET is effected.

36. The imprint lithography process as claimed in claim 31, wherein applying a polymeric gate dielectric layer comprises spin coating, printing or spraying.

37. The imprint lithography process as claimed in claim 31, wherein the crosslinking reaction is effected under an inert gas atmosphere.

38. The imprint lithography process as claimed in claim 31, and further comprising performing a drying step after applying the polymeric gate dielectric layer.

39. The imprint lithography process as claimed in claim 31, and further comprising applying a source-drain layer to the gate dielectric layer.

40. The imprint lithography process as claimed in claim 39, and further comprising applying an active layer for the formation of an OFET to the source-drain layer.

41. The imprint lithography process as claimed in claim 40, and futher comprising arranging a passivating layer over the active layer.
